(19) United States
(12) Patent Application Publication
(10) Pub. No.: US 2022/0047050 A1
(43) Pub. Date: Feb. 17, 2022

(54) PERSONAL ANTIMICROBIAL CARRIER

(71) Applicant: PAC X, LLC, Burlingame, CA (US)

(72) Inventors: Tamara Icardi Ferrari, Burlingame, CA (US); Carol McEnaney Leininger, Burlingame, CA (US)

(21) Appl. No.: 17/402,319

(22) Filed: Aug. 13, 2021

Related U.S. Application Data
(60) Provisional application No. 63/065,681, filed on Aug. 14, 2020.

(51) Int. Cl. A45C 1/02; C23C 16/06; D01F 11/12; D01F 1/10; A01N 59/20

(52) U.S. Cl. CPC A45C 1/02; C23C 16/06; D10B 2401/13; D01F 1/103; A01N 59/20; D01F 11/127

(57) ABSTRACT

An exemplary personal carrier includes a housing defining a space, and an antimicrobial metal incorporated into the housing. According to one exemplary embodiment, the housing can be any carrying type object and can include an anti-microbial material deposited or infused therein.

### CROSS-REFERENCE TO RELATED APPLICATIONS

This application claims the benefit of U.S. Provisional Pat. App. No. 63/065,681, filed 14 Aug. 2020, the disclosure of which is incorporated by reference herein in its entirety.

### BACKGROUND

The described embodiments relate generally to luggage. More particularly, the present embodiments relate to antimicrobial luggage, bags, wallets, and carriers for personal effects.

Infectious diseases can spread across any number of surfaces. Tests indicate that objects that are commonly touched or handled by a user are often the most germ infested surfaces. Often touched surfaces and objects such as coins, cell phones, cosmetics, money, credit cards, personal identification cards and keys are typically also very dirty and can be a source of disease transmission.

In addition to frequent hand washing and good hygiene habits, traditional solutions for combatting the issues associated with high-traffic objects have varied. A number of solutions include the use of a radiation source—like an ultraviolet (UV) radiation source—to bombard the high-traffic objects for sterilization. Other solutions include the incorporation of chemicals or disinfectants into a carrier of the high-traffic objects to actively sterilize the objects. However, in the case of a radiation source, the object often have to be transferred from a purse or a bag to reside in a radiation compartment. Additionally, the radiation source requires a power supply in the form of a plug or batteries. These inconveniences often lead to low compliance with the sterilization process. Furthermore, the inclusion of chemicals or disinfectants onto or into the material making up a carrier of the high-traffic objects only provides the anti-microbial effect for the useful life of the chemicals or disinfectants. This results in a partial solution that quickly deteriorates. Consequently, there is a need in the industry for a simple yet long-lasting antimicrobial solution to high-traffic surfaces.

### SUMMARY

An exemplary personal carrier includes a housing defining a space, and an antimicrobial metal incorporated into the housing. According to one exemplary embodiment, the housing can be luggage, a bag, a backpack, a wallet, a purse, a duffel bag, a lanyard, a pouch, a case, a phone case, a glasses case, an identification card case, a money clip, a compartment or pocket of a larger structure, or other similar structure.

In one exemplary embodiment, the housing can be formed of any number of materials including, but in no way limited to, cloth, leather, polymer, metal, foil, composite, and combinations thereof. The antimicrobial metal can include, but is in no way limited to, copper, silver, copper alloys, silver alloys, and combinations thereof. The antimicrobial metal can be associated with the housing in any number of ways including, but in no way limited to, painted, screen printed, weaved, dipped, vapor deposition, a mesh insert or liner, and the like. Furthermore, the objects that can be contained by the personal carrier include, but are in no way limited to, masks, identification, credit cards, clothes, sports equipment, beverages, electronics, school supplies, and the like.

In one example, an antimicrobial container includes a housing defining a volume, and an antimicrobial metal formed on a surface of the housing.

In some examples of the antimicrobial container, the antimicrobial metal is disposed on the surface of the housing within the volume. In other examples, the antimicrobial metal is disposed on an outer surface of the housing. In some examples, the antimicrobial metal is weaved into a fabric of the housing.

In some examples, the antimicrobial container includes the antimicrobial metal deposited onto the surface of the housing. The antimicrobial metal can be deposited, in some examples, via a vapor deposition process. In some examples, the antimicrobial metal is adhered by a binder and the antimicrobial metal and the binder are screen printed onto the surface of the housing. In some examples, the antimicrobial metal is twisted with a non-metal fiber to form a yarn.

The antimicrobial container can include an antimicrobial metal that comprises a copper or a copper alloy. Similarly, the antimicrobial metal can include at least one of silver, gold, platinum, palladium, iridium, zinc, tin, bismuth, antimony, or an alloy, oxide, carbide, nitride, boride, sulfide, myristate, stearate, oleate, glutonate, adipate, silicate, phosphide, halide, hydride, nitrate, carbonate, sulfadiazine, acetate, lactate, citrate, or alkali thiosulphate thereof.

In another embodiment, a personal carrier can include an outer housing, an inner surface, and a pocket defined by the personal carrier. According to this embodiment, the pocket is defined by a surface of the wallet including an antimicrobial metal formed on the surface.

In some examples, the surface including an antimicrobial metal includes a fabric including the antimicrobial metal weaved with a base material to form the fabric. In other examples, the antimicrobial metal is deposited onto the surface. According to some examples, the antimicrobial metal can be deposited via a vapor deposition process. Alternatively, the antimicrobial metal can be adhered to the surface by a binder and the antimicrobial metal and the binder can be screen printed onto the surface.

In some examples, the personal carrier can include an antimicrobial metal in the form of a copper or a copper alloy. In some examples, the antimicrobial metal can include at least one of silver, gold, platinum, palladium, iridium, zinc, tin, bismuth, antimony, or an alloy, oxide, carbide, nitride, boride, sulfide, myristate, stearate, oleate, glutonate, adipate, silicate, phosphide, halide, hydride, nitrate, carbonate, sulfadiazine, acetate, lactate, citrate, or alkali thiosulphate thereof.

In some examples, the personal carrier can be a wallet or a purse.

In another embodiment, an antimicrobial fabric includes a base material, and an antimicrobial metal engaging a surface of the base material, wherein the base material includes one of an animal fiber, a plat based fiber, a mineral fiber, or a synthetic fiber, and wherein the antimicrobial metal engaging a surface of the base material includes a copper or a copper alloy.

In one example of the antimicrobial fabric, the base material and the antimicrobial metal are weaved together to form the fabric.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a perspective view of a wallet with an antimicrobial metal coating, according to one exemplary embodiment.

FIG. 2 illustrates a perspective view of a purse including an antimicrobial metal coating, according to one exemplary embodiment.

FIG. 3a illustrates a top view of a weaved material including an interweaved antimicrobial metal, according to one exemplary embodiment.

FIG. 3b illustrates a side view of a twisted yarn including an antimicrobial metal, according to one exemplary embodiment.

FIG. 4 illustrates a side view of a material including an antimicrobial metal coating, according to one exemplary embodiment.

### DETAILED DESCRIPTION

The present description provides examples, and is not limiting of the scope, applicability, or configuration set forth in the claims. Thus, it will be understood that changes can be made in the function and arrangement of elements discussed without departing from the spirit and scope of the disclosure, and various embodiments can omit, substitute, or add other procedures or components, as appropriate. For instance, methods described can be performed in an order different from that described, and various steps can be added, omitted, or combined. Also, features described with respect to some embodiments can be combined in other embodiments.

The present exemplary systems and methods provide an exemplary personal carrier that includes a housing defining a space, and an antimicrobial metal incorporated into the housing. With recent outbreaks and pandemics around the world, people are more conscientious of all the surfaces that they are touching. Tests indicate that objects that are commonly touched or handled by a user are often the most germ infested surfaces. Often touched surfaces and objects such as coins, cell phones, cosmetics, money, credit cards, personal identification cards and keys are typically also very dirty and can be a source of disease transmission.

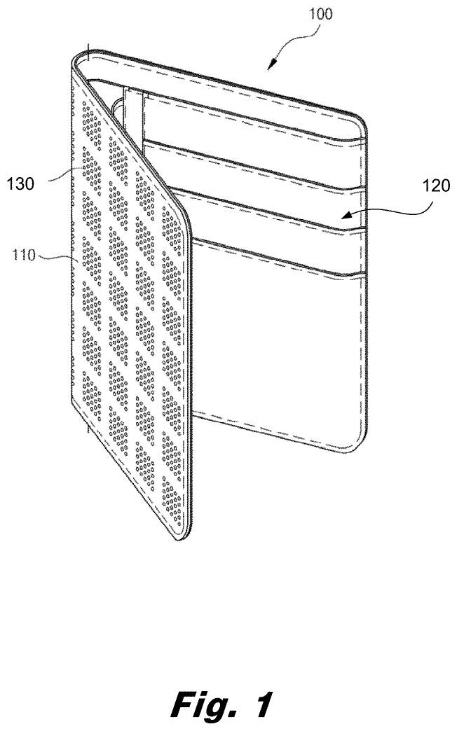

By incorporating an antimicrobial metal into the housing of a personal carrier, particularly on surfaces that are commonly touched or contain commonly touched items, the spread of germs and viruses can be reduced. These and other embodiments are discussed below with reference to FIGS. 1-4. However, those skilled in the art will readily appreciate that the detailed description given herein with respect to these FIGS. is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option). Various exemplary configurations and methods are detailed below, beginning with FIG. 1.

FIG. 1 illustrates an exemplary personal carrier, according to one exemplary embodiment. As shown, the exemplary personal carrier is a wallet 100. The wallet 100 includes an outer surface 110 and an inner surface 120 defining a number of card slots and pockets. Both the outer surface 110 and the inner surface 120 are frequently touched during use, and house commonly touched items such as credit cards, money, student ID cards, and the like. Consequently, one or both of the outer surface 110 and the inner surface 120 can be coated with an antimicrobial metal 130. Furthermore, interior surfaces of interior pockets or liners intended to come into contact with commonly touched items can be coated with an antimicrobial metal 130. Consequently, when a user's skin touches the antimicrobial metal 130, or a contaminated card or commonly touched item is placed in contact with the antimicrobial metal, the surface is substantially decontaminated. While the housing is illustrated in FIG. 1 as a wallet, the exemplary housing can be any repository or container including, but in no way limited to, luggage, a bag, a backpack, a wallet, a purse, a duffel bag, a lanyard, a pouch, a case, a phone case, a glasses case, an identification card case, a money clip, a compartment or pocket of a larger structure, or other similar structure.

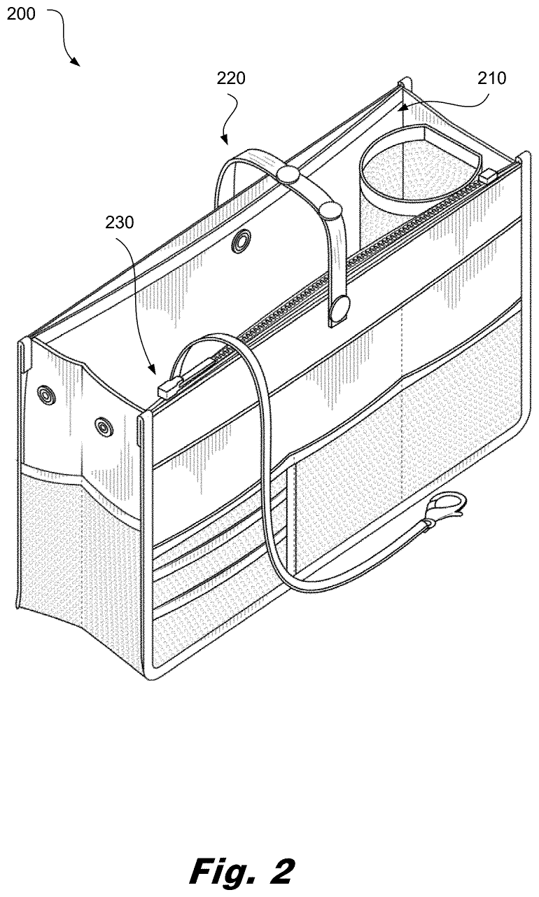

As shown in FIG. 2, the housing can be a bag or a purse 200. As shown in FIG. 2, bags with handles 220, such as a purse 200, have a number of specific locations where contact is frequently made with a user. For example a user will frequently touch the inside 210 of their purse, handles 220, zippers 230, and the like. While the wallet 100 of FIG. 1 was described as having an antimicrobial metal on all major surfaces, for larger items, such as a purse, all surfaces may include an antimicrobial metal, or selective high contact portions of the housing may be targeted for coating of the antimicrobial metal, such as the inside 210 of the purse, handles 220, zippers 230, and the like. In this embodiment, the remaining portions of the bag or purse are not coated and retain their original surface composition and aesthetic appeal, including natural and/or synthetic materials.

In one exemplary embodiment, the housing such as the wallet 100 and purse 200 can be formed of any number of materials including, but in no way limited to, cloth, leather, polymer, metal, foil, composite, and combinations thereof.

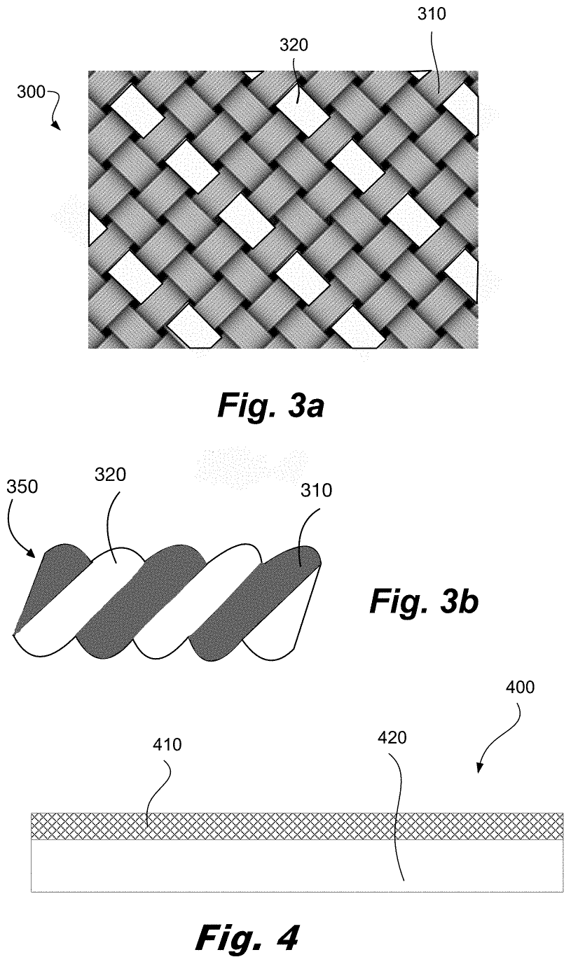

The antimicrobial metal can be associated or connected to the housing by any number of methods. As shown in FIG. 3a, the housing, or portions thereof, can be made of a weave material 300. According to one exemplary embodiment, the weaved material may include a base material 310 and an antimicrobial metal 320 weaved in with the base material to form a substrate or fabric that can be used to form the housing, or portions thereof.

According to one exemplary embodiment, the base material 310 can include any weavable fiber, including, but in no way limited to, animal fibers (such as alpaca, angora wool, azlon, byssus, camel hair, cashmere wool, chiengora, lambswool, llama, mohair wool, qiviut, rabbit, silk, eri silk, spider silk, vicuna, wool, or yak, etc.), plant based or cellulosic fibers (such as Abaca, acetate, baboo, banana, kapok, coir, cotton, flax, hemp, jute, kenaf, lyocell, modal, pina, raffia, ramie, rayon, sisal, or soy protein, etc.), mineral based fibers (such as carbon fiber, glasses or silicates, etc.), and/or synthetic fibers (such as acrylic, Kevlar, modacrylic, nomex, nylon, polyester, spandex, and rayon, etc.). The base material can be selected for any number of its properties including feel, texture, thermal properties, chemical resistance, durability, and the like. Additionally, various combinations of materials can be used to form the base material 310, as desired for various combinations of properties.

In contrast, the antimicrobial metal 320 can be any number of fibers incorporated into the weaved material to provide the antimicrobial properties mentioned above. According to one exemplary embodiment, the antimicrobial metal fibers 320 are pure metal fibers weaved into the weaved material. Alternatively, the antimicrobial metal fibers 320 can be a coated fiber with a core of a different material, which could be a different metal or a fiber. According to this example, the antimicrobial coating can be an outer coating of the composite fiber having a thickness of from 1-20 microns that has been applied via a PVD (physical vapor deposition) process. Alternatively, or in addition, the antimicrobial metal fiber 320 can form one or more threads or filaments plied together to form a yarn or thread including an antimicrobial metal 320, thereby imparting the antimicrobial characteristics to the resulting material made from the resulting yarn or threads.

The above-mentioned structure can, according to one example, be assembled using a twisting assembly method, as shown in FIG. 3b to produce a twisted yard 350. As shown in FIG. 3b, the antimicrobial metal 320 fibers and the base material fibers 310 are twisted together to form a yarn or string 350 that is then used to form a fabric. Alternatively, whole or complete threads of antimicrobial metal 320 and base material 310 can be weaved to form the fabric, as shown in FIG. 3a. According to one example, the yarn or fibers can be weaved together using any number of weaving methods and/or orientations including, but in no way limited to, knitting, felting, braiding, plaiting, plain or linen weave, oxford weave, twill weave, herringbone weave, dobby weave, satin weave, velvet weave, rib weave, basket weave, leno weave, sateen weave, crepe weave, lappe4t weave, tapestry weave, stripped weave, checquered weaves, double cloth weaves, and the like.

According to one embodiment the weave material can have a localized strip or other geometry that includes the antimicrobial metal fibers 310 to provide the desired antimicrobial effect in that location, or as an object is passed by the localized portion. This design can allow for customized design that optimizes the use of the antimicrobial metal. The remainder of the weave material can then be formed of the base material 310. In some examples, the antimicrobial metal fibers 310 substantially or completely make up the structure of a mesh insert or liner that can then be used as an insert over or under a fabric pocket of a personal carrier such as a purse, wallet, backpack, and the like. According to this example, there is little or no base material weaved with the antimicrobial metal, thereby substantially maximizing the available surface area of antimicrobial metal surface 410 to engage desired surfaces. In one embodiment, the antimicrobial metal mesh surface can be a mesh of a metal, such as copper, having a diameter of between 0.001 and 0.010 inches. According to one exemplary embodiment, the antimicrobial metal mesh is substantially made of metal wires having a diameter of approximately 0.002 inches. The resulting mesh insert or liner can be removable and/or inserted into various pockets or openings in a personal carrier and can line the surface thereof to provide the desired antimicrobial effect. The mesh insert or liner can be attached to a pocket or area using hook and loop, fasteners, adhesives, collars, by a sewn seam at a top of a pocket, and/or by frictional attachment.

Similarly, the weave material can be formed entirely of the base material, after which a portion of the material can then be selectively coated with the antimicrobial metal material via any number of deposition methods.

Alternatively, the antimicrobial metal could be formed on, be adhered to, line as an insert, or otherwise coat, a desired contact surface. According to one embodiment, an antimicrobial surface 400 can be formed on a base material 420 via a deposition process to form an antimicrobial metal surface 410 that can be used to form the housing. Alternatively, the antimicrobial metal can be deposited on the housing, or select portions of the housing, after formation of the housing. The antimicrobial metal can be deposited on the base material 420 in any number of ways including, but in no way limited to, painted, screen printed, dipped, vapor deposition, lined or adhered to, and the like.

According to one exemplary embodiment, the antimicrobial metal surface 410 is formed on the base material 420 via vapor deposition such as physical vapor deposition (PVD). PVD is a vacuum deposition method that can be used to produce thin films and coatings on any number of surfaces. According to one embodiment, the PVD process includes transitioning the antimicrobial metal from a condensed phase to a vapor phase. Once in a vapor phase, whether in another carrier material or not, the vapor can be applied to a surface to form a thin film. The application of the vapor can be accomplished by any number of deposition processes including, but in no way limited to sputtering or evaporation. According to some embodiments, the PVD thin film can range from 1 to 10 microns, or between 2 and 5 microns, or less, or greater. Alternatively, the antimicrobial metal can be deposited via any number of material deposition methods including, but in no way limited to electroplating, painting, spraying, and the like.

Once deposited, formed on, or otherwise inserted as a mesh, the antimicrobial metal-containing material combats the growth, propagation, and survival of microbes. Copper and its alloys, as well as other metals, act as natural antimicrobial materials. According to some theories, the antimicrobial metal containing metals have a number of molecular mechanisms that destroy a wide range of microorganisms, the antimicrobial mechanisms taking place both inside the cells and in the interstitial spaces between the cells. According to some embodiments, the antimicrobial metals can destroy microorganisms by altering the three-dimensional structure of proteins, thereby in activating bacteria or viruses; forming radicals that inactivate the viruses; disrupting enzyme structures and functions by binding to sulfur or carboxylate containing groups and amino groups of proteins; interfering with other essential elements; facilitating deleterious activity in superoxide radicals; causing peroxidation of lipids; impairing the cellular metabolism of cells; attacking the overall structure of viruses, inhibiting chemical reactions; causing oxidative stress and generating hydrogen peroxide, participating in the Fenton-type reaction; causing desiccation due to a decline in membrane integrity; and/or inappropriate protein binding. Various combinations of these mechanisms can have deleterious effects on a number of microorganisms that regularly contaminate surfaces including, but in no way limited to, E. coli, methicillin-resistant Staphylococcus aureus (MRSA), Staphylococcus, Clostridium difficile, influenza A virus, Fungi, and COVID-19.

Examples of antimicrobial metal-containing materials (which may or may not also be an atomically disordered crystalline material or a nanocrystalline material) that can be incorporated by the present exemplary systems and methods include, but are in no way limited to, antimicrobial silver-containing materials (e.g., antimicrobial silver, antimicrobial silver alloys, antimicrobial silver oxides, antimicrobial silver carbides, antimicrobial silver nitrides, antimicrobial silver borides, antimicrobial silver sulfides, antimicrobial silver myristates, antimicrobial silver stearates, antimicrobial silver oleates, antimicrobial silver glutonates, antimicrobial silver adipates, antimicrobial silver silicates, antimicrobial silver phosphides, antimicrobial silver halides, antimicrobial silver hydrides, antimicrobial silver nitrates, antimicrobial silver carbonates, antimicrobial silver sulfadiazines, antimicrobial silver acetates, antimicrobial silver lactates, antimicrobial silver citrates, antimicrobial alkali silver thiosulphates (e.g., antimicrobial sodium silver thiosulphate, antimicrobial potassium silver thiosulphate)), antimicrobial gold-containing materials (e.g., antimicrobial gold, antimicrobial gold alloys, antimicrobial gold oxides, antimicrobial gold carbides, antimicrobial gold nitrides, antimicrobial gold borides, antimicrobial gold sulfides, antimicrobial gold myristates, antimicrobial gold stearates, antimicrobial gold oleates, antimicrobial gold glutonates, antimicrobial gold glutonates, antimicrobial gold adipates, antimicrobial gold silicates, antimicrobial gold phosphides, antimicrobial gold halides, antimicrobial gold hydrides, antimicrobial gold nitrates, antimicrobial gold carbonates, antimicrobial gold sulfadiazines, antimicrobial gold acetates, antimicrobial gold lactates, antimicrobial gold citrates, antimicrobial alkali gold thiosulphates (e.g., antimicrobial sodium gold thiosulphate, antimicrobial potassium gold thiosulphate)), antimicrobial platinum-containing materials (e.g., antimicrobial platinum, antimicrobial platinum alloys, antimicrobial platinum oxides, antimicrobial platinum carbides, antimicrobial platinum nitrides, antimicrobial platinum borides, antimicrobial platinum sulfides, antimicrobial platinum myristates, antimicrobial platinum stearates, antimicrobial platinum oleates, antimicrobial platinum glutonates, antimicrobial platinum glutonates, antimicrobial platinum adipates, antimicrobial platinum silicates, antimicrobial platinum phosphides, antimicrobial platinum halides, antimicrobial platinum hydrides, antimicrobial platinum nitrates, antimicrobial platinum carbonates, antimicrobial platinum sulfadiazines, antimicrobial platinum acetates, antimicrobial platinum lactates, antimicrobial platinum citrates, antimicrobial alkali platinum thiosulphates (e.g., antimicrobial sodium platinum thiosulphate, antimicrobial potassium platinum thiosulphate)), antimicrobial palladium-containing materials (e.g., antimicrobial palladium, antimicrobial palladium alloys, antimicrobial palladium oxides, antimicrobial palladium carbides, antimicrobial palladium nitrides, antimicrobial palladium borides, antimicrobial palladium sulfides, antimicrobial palladium myristates, antimicrobial palladium stearates, antimicrobial palladium oleates, antimicrobial palladium glutonates, antimicrobial palladium glutonates, antimicrobial palladium adipates, antimicrobial palladium silicates, antimicrobial palladium phosphides, antimicrobial palladium halides, antimicrobial palladium hydrides, antimicrobial palladium nitrates, antimicrobial palladium carbonates, antimicrobial palladium sulfadiazines, antimicrobial palladium acetates, antimicrobial palladium lactates, antimicrobial palladium citrates, antimicrobial alkali palladium thiosulphates (e.g., antimicrobial sodium palladium thiosulphate, antimicrobial potassium palladium thiosulphate)), antimicrobial iridium-containing materials (e.g., antimicrobial iridium, antimicrobial iridium alloys, antimicrobial iridium oxides, antimicrobial iridium carbides, antimicrobial iridium nitrides, antimicrobial iridium borides, antimicrobial iridium sulfides, antimicrobial iridium myristates, antimicrobial iridium stearates, antimicrobial iridium oleates, antimicrobial iridium glutonates, antimicrobial iridium glutonates, antimicrobial iridium adipates, antimicrobial iridium silicates, antimicrobial iridium phosphides, antimicrobial iridium halides, antimicrobial iridium hydrides, antimicrobial iridium nitrates, antimicrobial iridium carbonates, antimicrobial iridium sulfides, antimicrobial iridium sulfadiazines; antimicrobial iridium acetates, antimicrobial iridium lactates, antimicrobial iridium citrates, antimicrobial alkali iridium thiosulphates (e.g., antimicrobial sodium iridium thiosulphate, antimicrobial potassium iridium thiosulphate)), antimicrobial zinc-containing materials (e.g., antimicrobial zinc, antimicrobial zinc alloys, antimicrobial zinc oxides, antimicrobial zinc carbides, antimicrobial zinc nitrides, antimicrobial zinc borides, antimicrobial zinc sulfides, antimicrobial zinc myristates, antimicrobial zinc stearates, antimicrobial zinc oleates, antimicrobial zinc glutonates, antimicrobial zinc glutonates, antimicrobial zinc adipates, antimicrobial zinc silicates, antimicrobial zinc phosphides, antimicrobial zinc halides, antimicrobial zinc hydrides, antimicrobial zinc nitrates, antimicrobial zinc carbonates, antimicrobial zinc sulfides, antimicrobial zinc sulfadiazines, antimicrobial zinc acetates, antimicrobial zinc lactates, antimicrobial zinc citrates, antimicrobial alkali zinc thiosulphates (e.g., antimicrobial sodium zinc thiosulphate, antimicrobial potassium zinc thiosulphate)), antimicrobial copper-containing materials (e.g., antimicrobial copper, antimicrobial copper alloys, antimicrobial copper oxides, antimicrobial copper carbides, antimicrobial copper nitrides, antimicrobial copper borides, antimicrobial copper sulfides, antimicrobial copper myristates, antimicrobial copper stearates, antimicrobial copper oleates, antimicrobial copper glutonates, antimicrobial copper glutonates, antimicrobial copper adipates, antimicrobial copper silicates, antimicrobial copper phosphides, antimicrobial copper halides, antimicrobial copper hydrides, antimicrobial copper nitrates, antimicrobial copper carbonates, antimicrobial copper sulfides, antimicrobial copper sulfadiazines, antimicrobial copper acetates, antimicrobial copper lactates, antimicrobial copper citrates, antimicrobial alkali copper thiosulphates (e.g., antimicrobial sodium copper thiosulphate, antimicrobial potassium copper thiosulphate)), antimicrobial tin-containing materials (e.g., antimicrobial tin, antimicrobial tin alloys, antimicrobial tin oxides, antimicrobial tin carbides, antimicrobial tin nitrides, antimicrobial tin borides, antimicrobial tin sulfides, antimicrobial tin myristates, antimicrobial tin stearates, antimicrobial tin oleates, antimicrobial tin glutonates, antimicrobial tin glutonates, antimicrobial tin adipates, antimicrobial tin silicates, antimicrobial tin phosphides, antimicrobial tin halides, antimicrobial tin hydrides, antimicrobial tin nitrates, antimicrobial tin carbonates, antimicrobial tin sulfides, antimicrobial tin sulfadiazines, antimicrobial tin acetates, antimicrobial tin lactates, antimicrobial tin citrates, antimicrobial alkali tin thiosulphates (e.g., antimicrobial sodium tin thiosulphate, antimicrobial potassium tin thiosulphate)), antimicrobial antimony-containing materials (e.g., antimicrobial antimony, antimicrobial antimony alloys, antimicrobial antimony oxides, antimicrobial antimony carbides, antimicrobial antimony nitrides, antimicrobial antimony borides, antimicrobial antimony sulfides, antimicrobial antimony myristates, antimicrobial antimony stearates, antimicrobial antimony oleates, antimicrobial antimony glutonates, antimicrobial antimony glutonates, antimicrobial antimony adipates, antimicrobial antimony silicates, antimicrobial antimony phosphides, antimicrobial antimony halides, antimicrobial antimony hydrides, antimicrobial antimony nitrates, antimicrobial antimony carbonates, antimicrobial antimony sulfides, antimicrobial antimony sulfadiazines, antimicrobial antimony acetates, antimicrobial antimony lactates, antimicrobial antimony citrates, antimicrobial alkali antimony thiosulphates (e.g., antimicrobial sodium antimony thiosulphate, antimicrobial potassium antimony thiosulphate)), antimicrobial bismuth containing materials (e.g., antimicrobial bismuth, antimicrobial bismuth alloys, antimicrobial bismuth oxides, antimicrobial bismuth carbides, antimicrobial bismuth nitrides, antimicrobial bismuth borides, antimicrobial bismuth sulfides, antimicrobial bismuth myristates, antimicrobial bismuth stearates, antimicrobial bismuth oleates, antimicrobial bismuth glutonates, antimicrobial bismuth glutonates, antimicrobial bismuth adipates, antimicrobial bismuth silicates, antimicrobial bismuth phosphides, antimicrobial bismuth halides, antimicrobial bismuth hydrides, antimicrobial bismuth nitrates, antimicrobial bismuth carbonates, antimicrobial bismuth sulfides, antimicrobial bismuth sulfadiazines, antimicrobial bismuth acetates, antimicrobial bismuth lactates, antimicrobial bismuth citrates, antimicrobial alkali bismuth thiosulphates (e.g., antimicrobial sodium bismuth thiosulphate, antimicrobial potassium bismuth thiosulphate)).

According to one exemplary embodiment illustrated in FIG. 4, the antimicrobial metal can be deposited on the desired surface by any deposition method including spraying, rolling, screen printing, roll printing, and the like. According to this exemplary embodiment the antimicrobial metal can be distributed in an ink or binder solution and then deposited on a fabric or other surface either by spray or direct roller or screen application. According to this embodiment, when the ink or binder adheres to the desired base material 420, the antimicrobial metal surface 410 is formed on the base material 420 and the antimicrobial metal particles can be exposed to the exterior of the antimicrobial surface 400 where it can engage and destroy unwanted microorganisms.

As used herein, the terms exterior, outer, interior, inner, top, and bottom are used for reference purposes only. An exterior or outer portion of a component can form a portion of an exterior surface of the component but may not necessarily form the entire exterior of outer surface thereof. Similarly, the interior or inner portion of a component can form or define an interior or inner portion of the component but can also form or define a portion of an exterior or outer surface of the component. A top portion of a component can be located above a bottom portion in some orientations of the component, but can also be located in line with, below, or in other spatial relationships with the bottom portion depending on the orientation of the component.

Additionally, while a large part of the present disclosure details a fabric including an antimicrobial metal incorporated therein, the present teachings and methods can be used to apply an antimicrobial metal coating to any number of surfaces or substrates including personal carriers such as wallets, purses, backpacks, and luggage; clothing, including pockets, liners for pockets, coats; storage compartments, and the like.

Various inventions have been described herein with reference to certain specific embodiments and examples. However, they will be recognized by those skilled in the art that many variations are possible without departing from the scope and spirit of the inventions disclosed herein, in that those inventions set forth in the claims below are intended to cover all variations and modifications of the inventions disclosed without departing from the spirit of the inventions. The terms “including:” and “having” come as used in the specification and claims shall have the same meaning as the term “comprising.”

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An antimicrobial container, comprising:
a housing defining a volume; and
an antimicrobial metal formed on a surface of the housing.

2. The antimicrobial container of claim 1, wherein the antimicrobial metal is disposed on the surface of the housing within the volume.

3. The antimicrobial container of claim 1, wherein the antimicrobial metal is disposed on an outer surface of the housing.

4. The antimicrobial container of claim 1, wherein the antimicrobial metal is weaved into a fabric of the housing.

5. The antimicrobial container of claim 1, wherein the antimicrobial metal is deposited onto the surface of the housing.

6. The antimicrobial container of claim 5, wherein the antimicrobial metal is deposited via a vapor deposition process.

7. The antimicrobial container of claim 5, wherein:
the antimicrobial metal is adhered by a binder; and
the antimicrobial metal and the binder are screen printed onto the surface of the housing.

8. The antimicrobial container of claim 1, wherein the antimicrobial metal comprises an antimicrobial mesh liner comprising metal wires having an approximately 0.002 inch diameter.

9. The antimicrobial container of claim 1, wherein the antimicrobial metal comprises a copper or a copper alloy.

10. The antimicrobial container of claim 1, wherein the antimicrobial metal comprises at least one of silver, gold, platinum, palladium, iridium, zinc, tin, bismuth, antimony, or an alloy, oxide, carbide, nitride, boride, sulfide, myristate, stearate, oleate, glutonate, adipate, silicate, phosphide, halide, hydride, nitrate, carbonate, sulfadiazine, acetate, lactate, citrate, or alkali thiosulphate thereof.

11. A personal carrier, comprising:
an outer housing;
an inner surface; and
a pocket defined by the personal carrier;
wherein the pocket is defined by a surface of the wallet including an antimicrobial metal formed on the surface.

12. The personal carrier of claim 11, wherein the surface including an antimicrobial metal comprises a fabric including the antimicrobial metal weaved with a base material to form the fabric.

13. The personal carrier of claim 11, wherein the antimicrobial metal comprises a metal mesh liner disposed in the pocket.

14. The personal carrier of claim 13, wherein:
the antimicrobial metal is adhered to the surface by a binder; and
the antimicrobial metal and the binder are screen printed onto the surface.

15. The personal carrier of claim 11, wherein the antimicrobial metal is twisted with a non-metal fiber to form a yarn.

16. The personal carrier of claim 11, wherein the antimicrobial metal comprises a copper or a copper alloy.

17. The personal carrier of claim 11, wherein the antimicrobial metal comprises at least one of silver, gold, platinum, palladium, iridium, zinc, tin, bismuth, antimony, or an alloy, oxide, carbide, nitride, boride, sulfide, myristate, stearate, oleate, glutonate, adipate, silicate, phosphide, halide, hydride, nitrate, carbonate, sulfadiazine, acetate, lactate, citrate, or alkali thiosulphate thereof.

18. The personal carrier of claim 11, wherein the personal carrier comprises one of a wallet or a purse.

19. An antimicrobial fabric, comprising:
a base material; and
an antimicrobial metal engaging a surface of the base material;
wherein the base material comprises one of an animal fiber, a plat based fiber, a mineral fiber, or a synthetic fiber; and
wherein the antimicrobial metal engaging a surface of the base material comprises a copper or a copper alloy.

20. The antimicrobial fabric of claim 19, wherein the antimicrobial metal comprises a liner disposed on a surface of the base material.
